(19) United States
(12) Patent Application Publication
(10) Pub. No.: US 2006/0238278 A1
(43) Pub. Date: Oct. 26, 2006

(54) Digital broadcasting reception device

(75) Inventor: Atsushi Kakiuchi, Echizen-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Echizen-city (JP)

(21) Appl. No.: 11/408,968

(22) Filed: Apr. 24, 2006

(30) Foreign Application Priority Data
Apr. 26, 2005 (JP) 2005-128160

(51) Int. Cl. H03J 3/00

(52) U.S. Cl. 334/85

(57) ABSTRACT

A digital broadcasting reception device capable of accommodating a plurality of types of substrates having different mounting positions of parts in a common shielding case, having a higher degree of freedom and intended to reduce costs is provided. Inside a digital television is provided a metal shielding case wrapping around a substrate mounted with an electronic part and a detachable separation section in the shielding case. When accommodating a digital substrate having substantially the same size as that of this shielding case in the shielding case, the digital substrate is accommodated as is, and when a digital tuner mounted on the digital substrate which is smaller than this digital substrate exceeds the height of the shielding case, the digital tuner is placed at the position where the separation section is detached from the shielding case.

The present application is based on and claims priority of Japanese patent application No. 2005-128160 filed on Apr. 26, 2005, the entire contents of which are hereby incorporated by reference.

### BACKGROUND OF THE INVENTION

1. Field of the Invention

The present invention relates to a digital broadcasting reception device commonly using a shielding case for shielding electromagnetic noise.

2. Description of the Related Art

Conventionally, a digital circuit substrate mounted with a heat-generating part such as a video processing section provided for a digital broadcasting reception device such as a digital television has the nature of generating heat and noise when it is electrically connected, and therefore it often produces mutual interference among various electronic parts mounted on a circuit substrate neighboring this heat-generating part, and to solve such problems possibly caused by interference, the substrate on which the electronic part is mounted is wrapped around with a shielding case made of a metallic member for shielding noise. Furthermore, when the heat-generating part is covered in such a way as to be wrapped around with the shielding case, the interior of the shielding case is filled with heat generated and produces a high temperature, and therefore to radiate heat so as to prevent heat from filling the interior of the shielding case, the heat-generating part and part of the shielding case are connected directly or through a metal fragment or the like, heat is conducted to the shielding case, made radiate from the surface of this shielding case or vent holes are formed in the shielding case and so on to control heat or radiation noise generated in the heat-generating part. However, providing such a shielding case as noise or heat controlling measures involves a problem of increasing the number of parts and thereby increasing the cost.

As such a related art, Japanese Patent Laid-Open Publication No.9-64582 (Patent Document 1) discloses a method of providing a metal piece inverted in a trapezoid shape on the inner side of a planar part of a top cover of the shielding case in accordance with the mounting position of the heat-generating part mounted on the substrate, making the metal piece contact the heat-generating part and thereby commonly using the shielding case.

However, the method described in Patent Document 1 or the like provides a metal piece for a shielding case so as to contact a heat-generating part in accordance with the mounting position of the heat-generating part, but it takes no account of the size of a circuit substrate and the height of a part to be mounted, and is designed to accommodate only a single substrate of a predetermined size in the shielding case, and so there are limitations on the size and position of the substrate accommodated.

### SUMMARY OF THE INVENTION

The present invention has been implemented in view of the above related art and it is an object of the present invention to provide a digital broadcasting reception device, capable of accommodating a plurality of types of substrates having different mounting positions of parts in a common shielding case, having a high degree of freedom and designed to achieve a cost reduction.

The digital broadcasting reception device according to a first aspect of the present invention is a digital broadcasting reception device comprising a metal shielding case which wraps around a substrate mounted with an electronic part, wherein the digital broadcasting reception device forms a detachable separation section in the shielding case, forms parallel grooves in the shielding case in such a way that a shaving can be formed, accommodates, when a substrate having substantially the same size as that of the shielding case is accommodated in the shielding case, the substrate without detaching the separation section or raising the shaving, raises the shaving, when a substrate smaller than this substrate is accommodated in the shielding case, mounts the small substrate on this shaving, detaches the separation section from the shielding case when the height of the part mounted on the small substrate exceeds the height of the shielding case, and provides the part whose height exceeds the height of the shielding case in the space produced by this detachment.

According to the construction of the first aspect of the present invention, the use of the common shielding case eliminates the necessity for manufacturing a plurality of types of shielding cases for different substrates and when accommodating a substrate having substantially the same size as the shielding case in the shielding case, the substrate can be accommodated in this shielding case without working the shielding case, whereas when accommodating a substrate which is smaller than the substrate having substantially the same size as the shielding case and which is mounted with a part having a greater height than the height of the shielding case in the shielding case, the shaving is formed, the small substrate is mounted on this shaving and the part having a greater height than the height of the shielding case is placed at a position at which the separation section is detached, and it is possible to thereby accommodate substrates of different sizes in the shielding case commonly.

The digital broadcasting reception device according to a second aspect of the present invention is the digital broadcasting reception device according to the first aspect of the present invention, wherein the part whose height exceeds the height of the shielding case mounted on the small substrate is a digital tuner, the digital tuner is mounted face down in the horizontal direction on the substrate having substantially the same size as that of the shielding case, whereas the digital tuner is mounted upright in the vertical direction on the small substrate.

According to the construction of the second aspect of the present invention, the digital tuner is a part essential to a digital broadcasting reception device which receives digital broadcasting and outputs a video signal, which is generally made up of a substantially rectangular parallelepiped, but relatively larger than other parts and when such a digital tuner is mounted on a small substrate in the horizontal direction, it occupies a large mounting area, which is unsuitable, but by mounting the digital tuner on the small substrate in the vertical direction, it is possible to mount the digital tuner even on a relatively small substrate.

### BRIEF DESCRIPTION OF THE DRAWINGS

FIG. 1 is a perspective view of a digital television as an example of the present invention;

FIG. 2 is a rear view of the digital television in the above described example with the back cabinet removed;

FIG. 3 is a rear view of main components of the digital television in the above described example with the back cabinet removed;

FIG. 4 is a perspective view of the top cover of the shielding case provided for the digital television in the above described example;

FIG. 5 is a section view of the top cover of the shielding case in the above described example;

FIG. 6 is a perspective view of the bottom cover of the shielding case in the above described example;

FIG. 7 illustrates the above described example with the digital substrate mounted with a card slot placed on the bottom cover;

FIG. 8 is an exploded perspective view of the shielding case made up of the top cover and bottom cover in the above described example;

FIG. 9 is a perspective view of the shielding case accommodating the digital substrate mounted with the card slot in the above described example;

FIG. 10 is a rear view of the digital television in the above described example with the back cabinet removed;

FIG. 11 is a perspective view of the above described example with the separation section detached from the top cover of the shielding case;

FIG. 12 is a perspective view of the above described example with a trapezoid-shaped shaving formed on the bottom cover of the shielding case;

FIG. 13 is a section view of the above described example with the trapezoid-shaped shaving formed on the bottom cover of the shielding case;

FIG. 14 illustrates the above described example with the digital substrate with no card slot placed on the bottom cover;

FIG. 15 is a perspective view of the shielding case accommodating the digital substrate with no card slot in the above described example; and

FIG. 16 is an exploded perspective view of the shielding case in the above described example with the top cover from which the separation section is detached and a trapezoid-shaped shaving formed on the bottom cover.

### DETAILED DESCRIPTION OF THE PREFERRED EMBODIMENTS

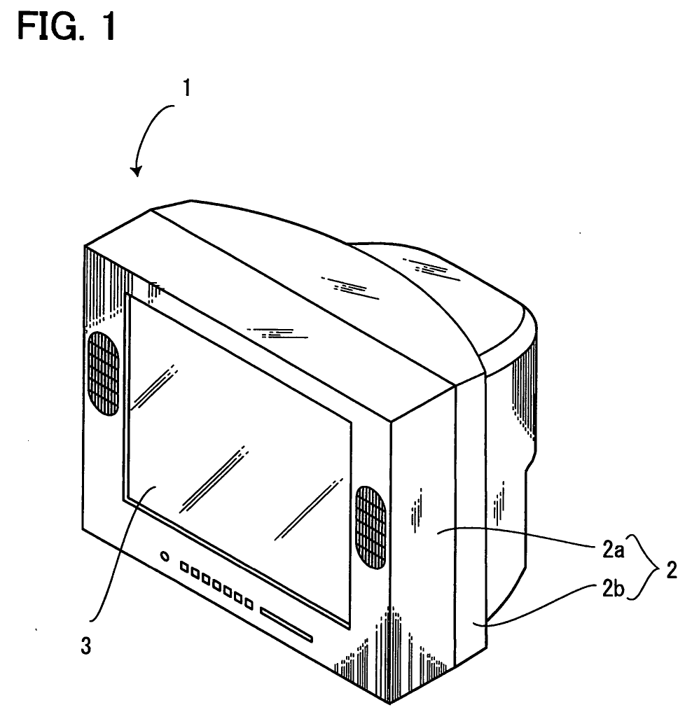

An embodiment as the best mode for implementing the present invention will be explained below with reference to FIG. 1 to FIG. 16. However, it goes without saying that the present invention is also easily applicable to modes other than that explained in the embodiment within a range not departing from the essence of the present invention.

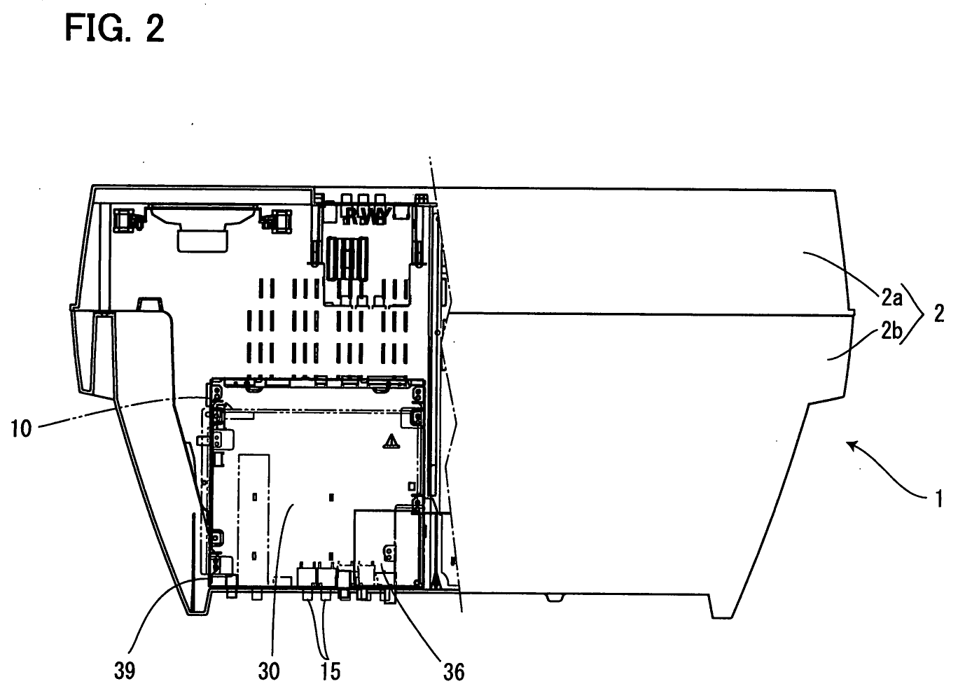

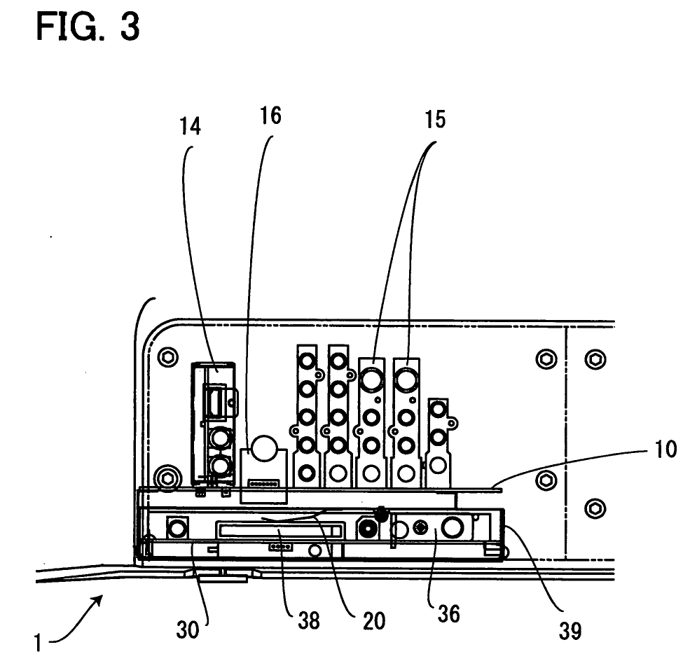

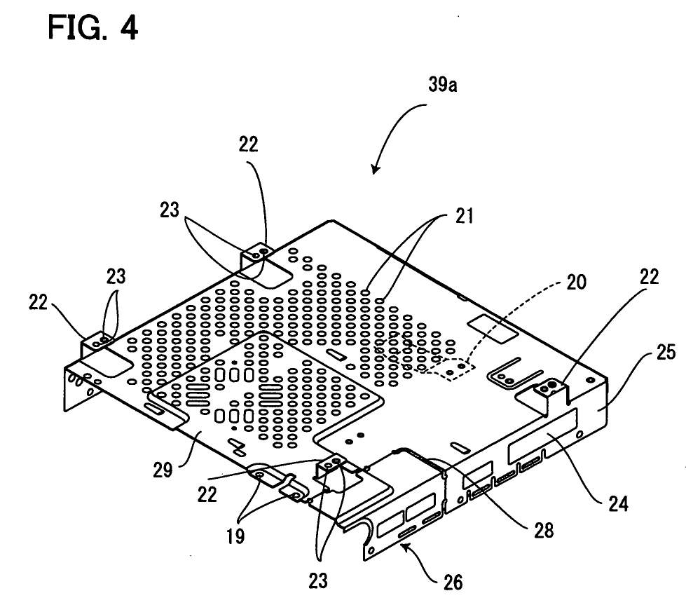

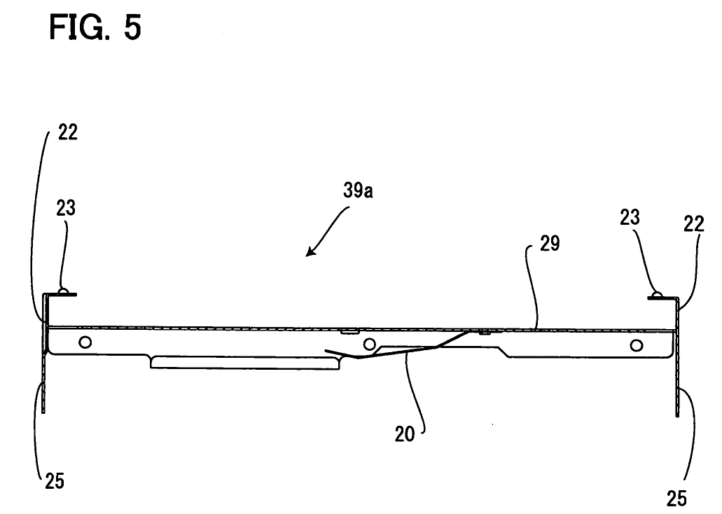

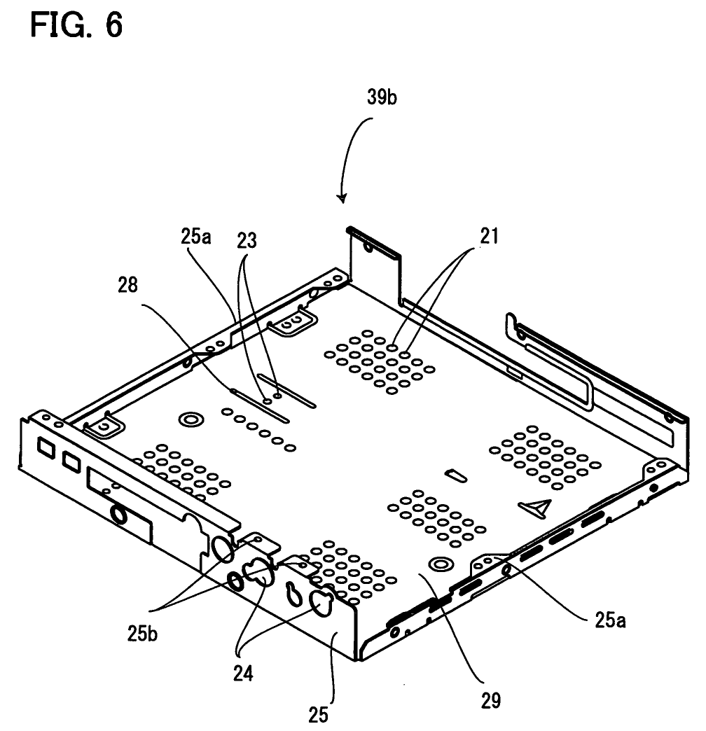

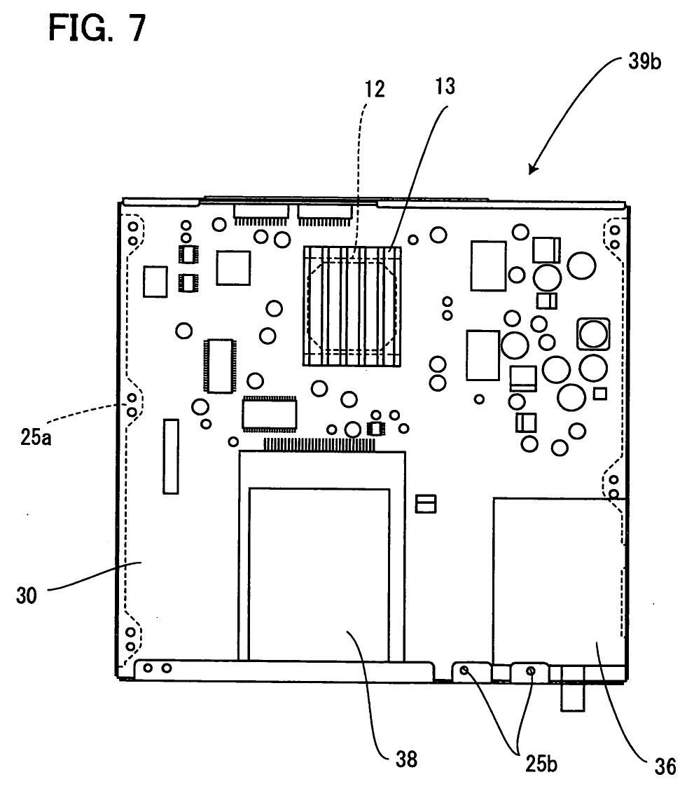

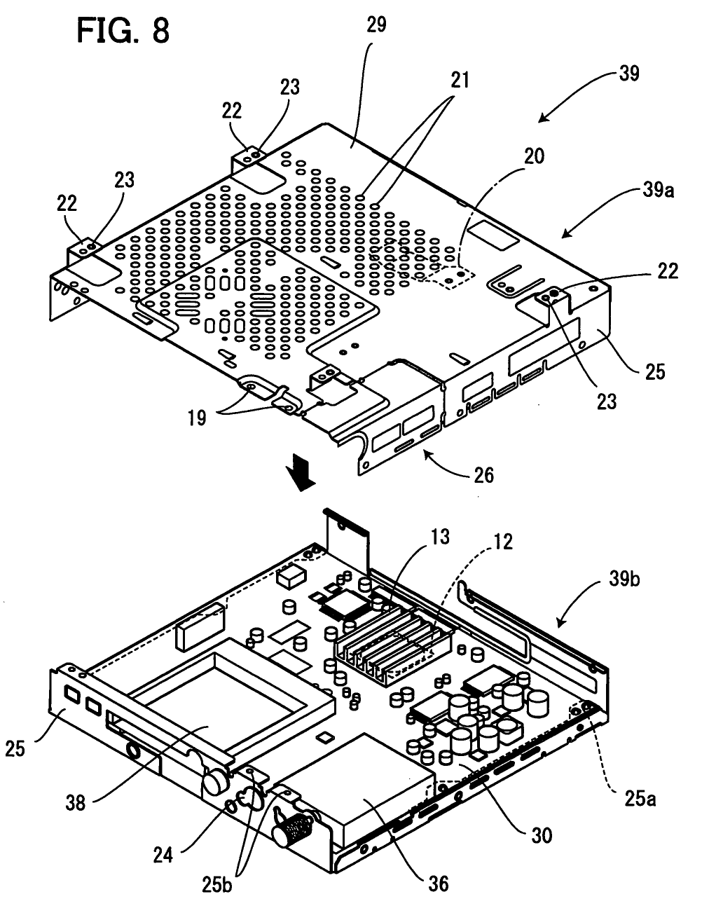

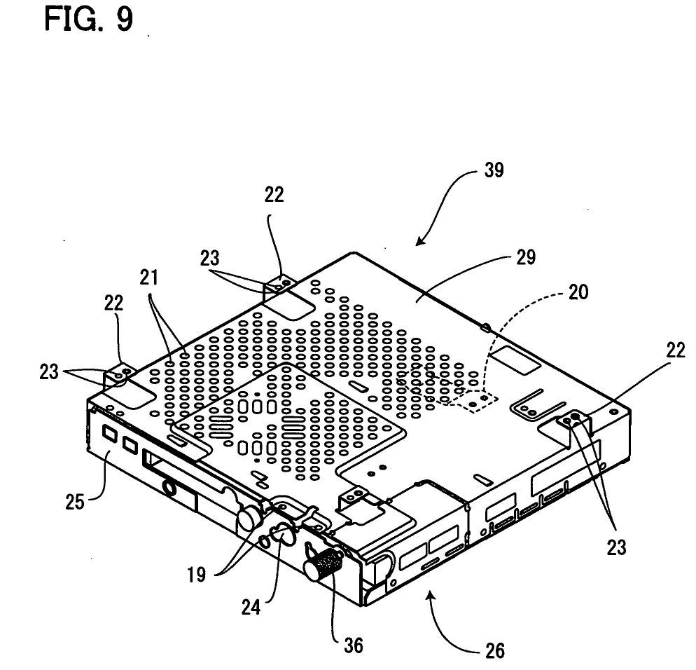

FIG. 1 is a perspective view of a digital television, FIG. 2 is a rear view of the digital television with the back cabinet removed, FIG. 3 is a rear view of main components of the digital television with the back cabinet removed, FIG. 4 is a perspective view of the top cover of the shielding case provided for the digital television, FIG. 5 is a section view of the top cover of the shielding case, FIG. 6 is a perspective view of the bottom cover of the shielding case, FIG. 7 illustrates the digital substrate loaded with a card slot mounted on the bottom cover, FIG. 8 is an exploded perspective view of the shielding case made up of the top cover and bottom cover and FIG. 9 is a perspective view of the shielding case accommodating the digital substrate loaded with the card slot.

As shown in FIG. 1, the outline of a digital television 1 which is a digital broadcasting reception device is composed of a substantially box-shaped synthetic resin cabinet 2, this cabinet 2 is constructed of a front cabinet 2a and back cabinet 2b which can be divided in a manner attachable/detachable back and forth and a display section 3 which displays a video image is provided in the center on the front of the front cabinet 2a.

Inside the cabinet 2, an AV (Audio and Visual) circuit substrate 10 which selects a predetermined video/audio signal from analog video/audio signals and digital video/audio signals input from jacks 15 connected to other electronic apparatuses and selects a predetermined voice signal from the selected analog voice signal and digital voice signal is placed horizontally, this AV circuit substrate 10 and a digital circuit substrate 30 mounted with a card slot 38 are arranged in parallel as two layers and the digital circuit substrate 30, one of these planar substrates 10, 30, mounted with various parts which will be described later is covered with a metal shielding case 39 which shields electromagnetic radiation in such a way as to be wrapped around.

Furthermore, various electronic parts or the like mounted on the digital substrate 30 generally emit electromagnetic radiation when the power to the digital television 1 is ON, and might affect other electronic apparatuses located adjacent to the digital television 1 or electronic parts arranged in the vicinity of the digital substrate 30 susceptible to electromagnetic radiation noise, and therefore to prevent this, this embodiment accommodates the digital substrate 30 in the thin, substantially box-shaped shielding case 39 which shields noise such as electromagnetic radiation in such a way as to wrap around the digital substrate 30 so as to prevent electromagnetic radiation emitted from the electronic parts mounted on the digital substrate 30 from affecting various electronic parts mounted on the AV circuit substrate 10 or the like susceptible to electromagnetic radiation by shielding electromagnetic radiation with the metal shielding case 39. The digital substrate 30 mounted with the card slot 38 has substantially the same size as the outline of the shielding case 39 as shown in FIG. 7, constitutes a broadcasting reception circuit capable of receiving digital broadcasting and is accommodated in the shielding case 39. The card slot 38 is used when receiving charged broadcasting and designed to be able to receive digital broadcasting by inserting a user card for charged broadcasting.

Furthermore, a plurality of small vent holes 21 are formed in this shielding case 39 to radiate heat generated in the video processing section 12 of this shielding case 39 filling the interior of the shielding case 39 and connecting the inner surface of the shielding case 39 and the surface of the video processing section 12 accommodated in the shielding case 39 through a metal plate spring 20 causes heat from the video processing section 12 as a heat-generating part to transfer from the plate spring 20 to the shielding case 39 having a relatively large surface area, making it possible to realize effective heat radiation.

Furthermore, the AV circuit substrate 10 is provided with a digital interface section 14, video correction section 16 and jacks 15 or the like used for connections with other electronic apparatuses and the AV circuit substrate 10 is electrically connected to the digital substrate 30 mounted with the card slot 38.

The digital circuit substrate 30 is mounted with the aforementioned card slot 38, video processing section 12, digital tuner 36 which lies face down in a horizontal direction for receiving a digital broadcast signal and various electronic parts or the like and the digital circuit substrate 30 is placed on substrate mounting sections 25a formed on the outer edges of a bottom cover 39b of the shielding case 39, and with both ends of the substrate 30 fixed, holes 25b of the bottom cover 39b and holes 19 of the top cover 39a are aligned as shown in FIG. 8, screws are inserted into the holes 25b and mounting holes 23, and the top cover 39a and bottom cover 39b are fixed with screws and united.

A radiation member 13 made of a metallic member for controlling heat radiation and electromagnetic radiation is provided on the top surface of the video processing section 12 which is a heat-generating component and one end thereof is pushed by an elastic force of the plate spring 20 which is fixed to the top cover 39a so that the video processing section 12 and radiation member 13 are reliably kept in contact with each other.

Here, the shielding case 39 will be explained more specifically. The aforementioned plurality of small vent holes 21 for radiating heat generated from the video processing section 12 are formed in the flat surface 29 of the top surface and bottom surface of the shielding case 39 and top cover 39a and bottom cover 39b, and a side wall 25 is provided with part insertion holes 24 to allow various parts to be inserted. The side wall 25 is formed at right angles with respect to the flat surface 29 and continuous thereto, and the shielding case 39 forms a substantially rectangular parallelepiped by combining the top cover 39a and bottom cover 39b into one body.

As shown in FIG. 4 and FIG. 5, the top cover 39a is provided with inverted L-figured protruding pieces 22 in which mounting holes 23 are formed and which protrude upward from the flat surface 29 and are formed integral with the top cover 39a, and the AV circuit substrate 10 is fixed by screws to the mounting holes 23.

Furthermore, when instead of the digital substrate 30 mounted with the card slot 38, a digital circuit substrate 40 which is smaller than the digital substrate 30 and mounted with no card slot 38 is mounted in the shielding case 39, by detaching a separation section 26 from grooves 28 formed in the top cover 39a and forming a shaving 27 which is the portion between two grooves 28 formed in parallel in the flat surface 29 of the bottom cover 39b made protrude into a trapezoid shape, it is possible to detach part of the shielding case 39, work and simply change the form of the shielding case 39. When the digital circuit substrate 30 mounted with the card slot 38 is accommodated in the aforementioned shielding case 39, the digital circuit substrate 30 is placed on the substrate mounting section 25a formed to be one step lower than the flat surface 29 of the top cover 39a which is formed at right angles with respect to the sidewall 25 and continuous thereto, it is possible to unite and fix the top cover 39a and bottom cover 39b or detach the separation section 26, make the portion between the grooves 28 protrude into a trapezoid shape, fix one end of the digital circuit substrate 40 with no card slot 38 and accommodate the digital circuit substrate 40 with no card slot 38, which is smaller than the digital circuit substrate 30 mounted with the card slot 38 and which will be described later, in the common shielding case 39.

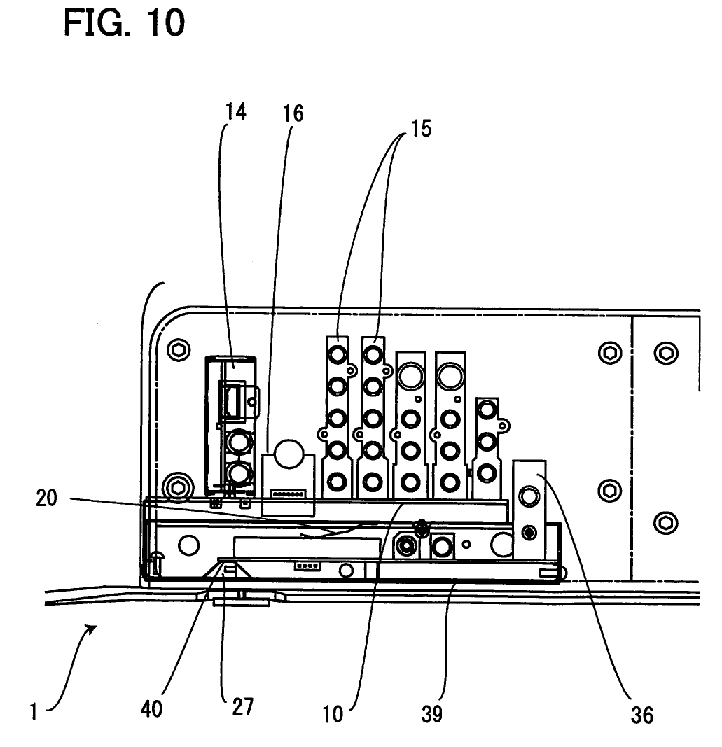

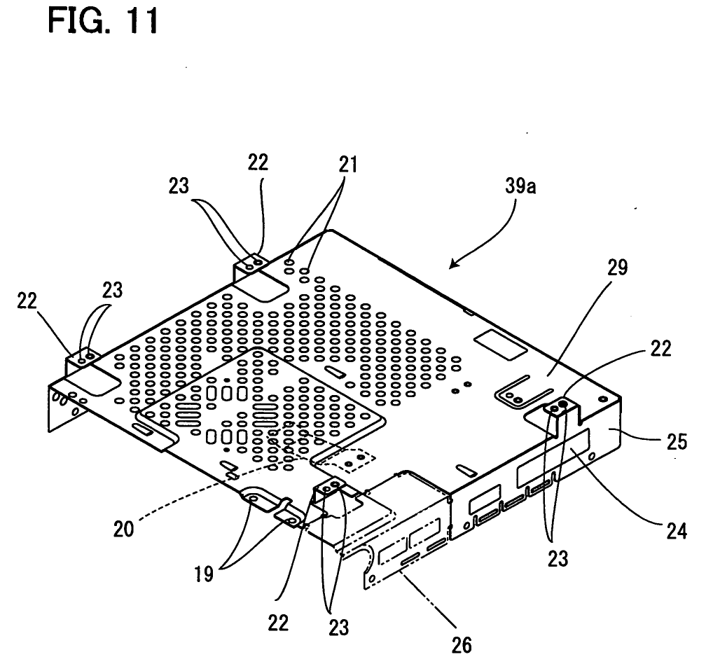

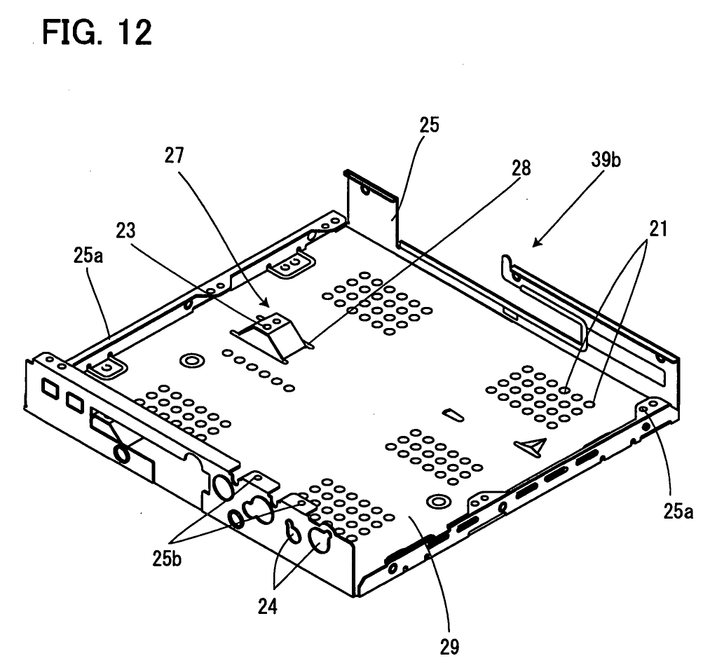

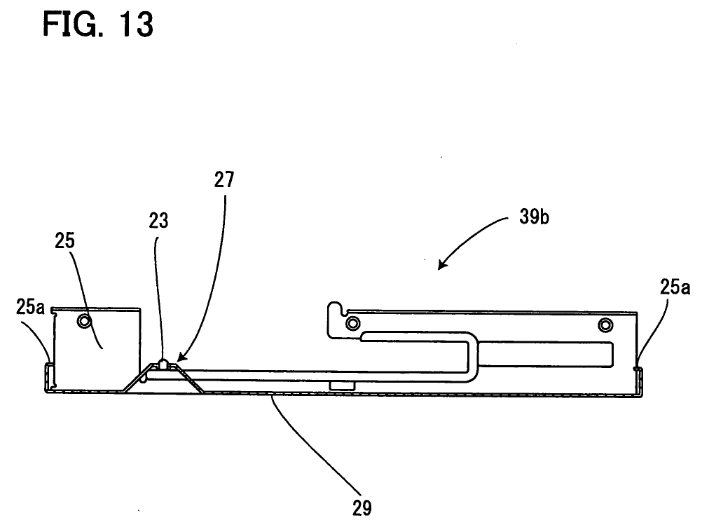

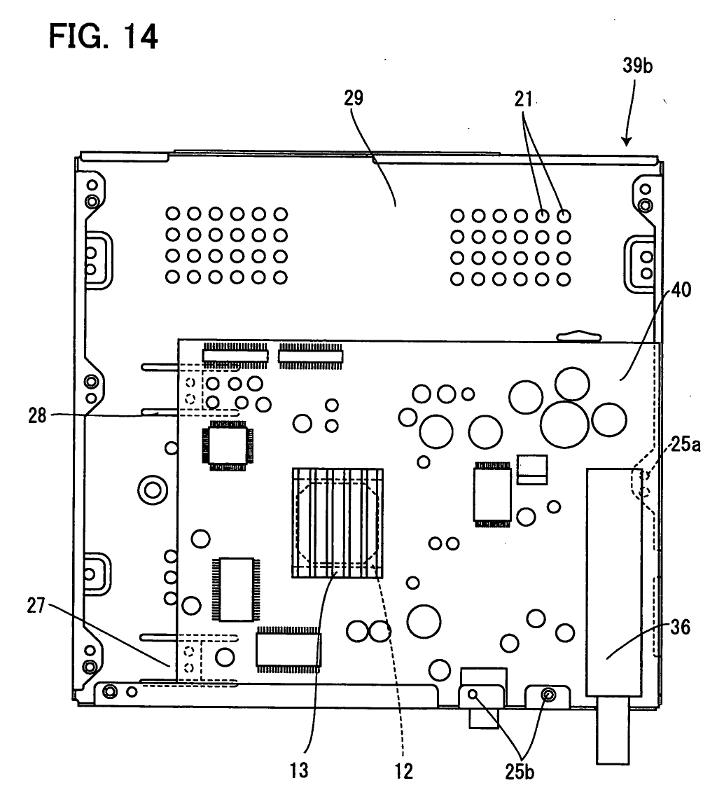

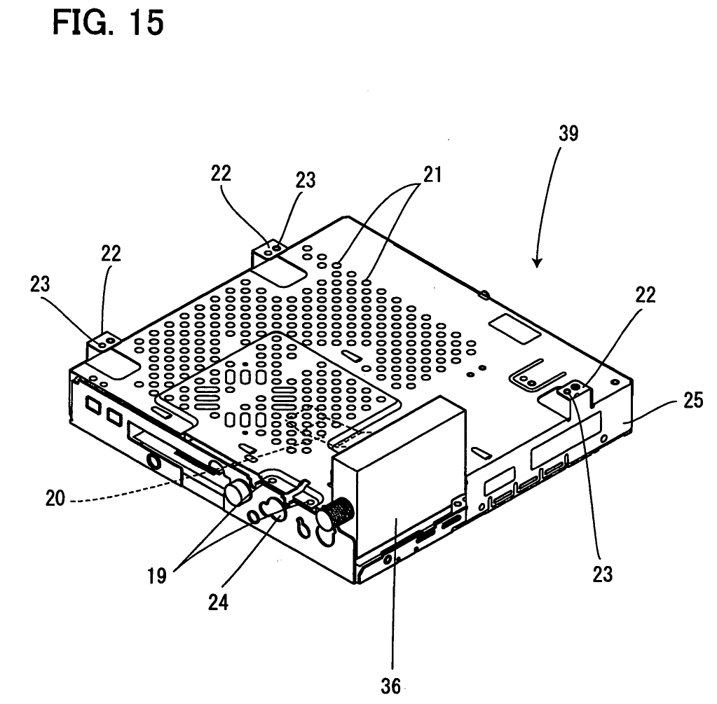

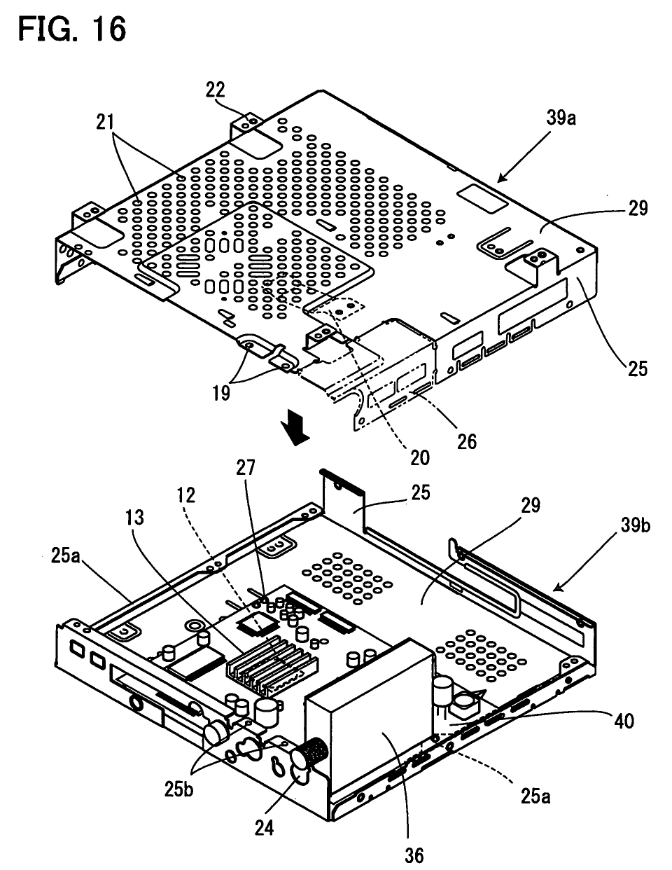

Next, the state in which the digital circuit substrate 40 with no card slot, which is smaller than the digital circuit substrate 30, is accommodated in the shielding case 39 which has been adapted so as to achieve commonality will be explained using FIG. 10 to FIG. 16. FIG. 10 is a rear view of the digital television with the back cabinet removed as in the case of FIG. 3, FIG. 11 is a perspective view with the separation section detached from the top cover of the shielding case, FIG. 12 is a perspective view of a trapezoid-shaped shaving formed on the bottom cover of the shielding case, FIG. 13 is a section view of a trapezoid-shaped shaving formed on the bottom cover of the shielding case, FIG. 14 illustrates a digital substrate with no card slot mounted on the bottom cover, FIG. 15 is a perspective view of the shielding case accommodating the digital substrate with no cards lot and FIG. 16 is an exploded perspective view of the shielding case with the top cover from which the separation section is detached and the trapezoid-shaped shaving formed on the bottom cover.

As shown in FIG. 2 and FIG. 14, the shielding case 39 accommodates the digital substrate 40 with no card slot, which is smaller than the outside shape of this shielding case 39 and is different from the structure shown in FIG. 1 to FIG. 9 in that since the small digital substrate 40 with no card slot 38, which is smaller than the digital substrate 30 mounted with the card slot 38 is placed, it is difficult to mount the digital tuner 36 face down on the digital substrate 40 due to spatial limitations on the surface area of the digital substrate 40, and therefore the digital tuner 36 is mounted upright in the vertical direction on the digital substrate 40 and the mounting position of the video processing section 12 which is a heat-generating part is different, and in order to mount the digital tuner 36 upright in the vertical direction on the digital substrate 40 and accommodate the digital substrate 40 in a predetermined position of the shielding case 39, by detaching the separation section 26 of the top cover 39a and forming the trapezoid-shaped shaving 27 on the bottom cover 39b in accordance with the size of the digital substrate 40 as shown in FIG. 11 and FIG. 12, it is possible to connect the video processing section 12 mounted on the digital substrate 40 to the top cover 39a through the plate spring 20, combine the top cover 39a and bottom cover 39b as one body, and it is possible to thereby detach the separation section 26 of the top cover 39a of the shielding case 39, adjust the size of the trapezoid-shaped shaving 27 of the bottom cover 39b from the digital substrate 30 to the different digital substrate 40 and simply work part of the shielding case 39 and thereby accommodate the substrates of different sizes in the common shielding case 39.

When the digital substrate 40 with no card slot 38 is placed at a predetermined position of the shielding case 39, if the digital tuner 36 is mounted in the vertical direction perpendicular to the horizontal digital substrate 40, the height of the digital tuner 36 exceeds the height of shielding case 39, and therefore the substantially L-figured separation section 26 formed on the top cover 39a beforehand is completely detached from the groove 28 of the top cover 39a and the digital tuner 36 is placed longitudinally using the space produced by this detachment, and by raising the portion between two parallel grooves 28 formed in the flat surface 29 of the bottom cover 39b so as to protrude, forming the trapezoid-shaped shaving 27 and forming the top surface of the shaving 27 so that the top surface of this shaving 27 has the same height as that of the substrate mounting section 25a, it is possible to place the digital substrate 40 horizontally on the shaving 27 in the shielding case 39 and fix the digital substrate 40 to the mounting holes 23 formed in the shaving 27 by screws or the like.

As shown above, with the digital television 1 according to this embodiment which allows the shielding case 39 to be used commonly, it is possible to form the grooves 28 in the top cover 39a of the shielding case 39 beforehand, provide the separation section 26 detachable from the grooves 28 in the top cover 39a, form the shaving 27 made up of two parallel grooves 28 which can be raised in a trapezoid shape on the bottom cover 39b, and when accommodating the digital substrate 30 mounted with the card slot 38 having substantially the same size as the shielding case 39 in the shielding case 39, it is possible to place and accommodate the digital substrate 30 on the substrate mounting section 25a as is without detaching the separation section 26 or raising the shaving 27, and on the other hand, when accommodating the digital substrate 40 which is smaller than the substrate 30 mounted with the card slot 38 in the shielding case 39, it is possible to mount the digital tuner 36 on this digital substrate 40 in the vertical direction, detach the separation section 26 from the groove 28 of the top cover 39a, form the shaving 27 of the bottom cover 39b so as to protrude in a trapezoid shape, place and fix one end of the digital substrate 40 on the substrate mounting section 25a provided in such a way that the top surface of the shaving 27 is level to the substrate mounting section 25a, fix the other end to the shaving 27 and accommodate it in the shielding case 39. That is, even when heights and arrangement of parts such as the digital tuner 36 mounted on the substrates 30, 40 are different, it is possible to assemble those parts in the common shielding case 39, and even when the sizes of the substrates 30, 40 are different, it is possible to obtain a similar radiation effect by fixing both ends of the substrates 30, 40 to the shielding case 39 and thereby increase the degree of freedom of arrangement/construction, achieve commonality, reduce costs and eventually provide a low-cost digital television 1.

Furthermore, the plate spring 20 is the metal fragment which has heat conductivity, one end of which is fixed to the top cover 39a and when the top cover 39a and bottom cover 39b of the shielding case 39 are combined into one body, the plate spring 20 elastically urges the video processing section 12 which is a heat-generating part, and therefore it is possible to connect this video processing section 12 or the radiation member 13 contacting this video processing section 12 to the inner surface of the top cover 39a, radiate heat from the metallic shielding case 39 having a relatively large surface area, and thereby effectively radiate heat from the video processing section 12.

Furthermore, the digital television 1 can accommodate the digital substrate 30 mounted with the card slot 38 having substantially the same size as that of the shielding case 39 or the digital substrate 40 which is smaller than the digital substrate 30 in the common shielding case 39, eliminate the necessity for manufacturing a plurality of types of the shielding case 39 in accordance with the heights and positions of parts such as the digital tuner 36 when the digital substrates 30, 40 are mounted in the shielding case 39 and thereby reduce the manufacturing cost.

Furthermore, the digital substrates 30, 40 are relatively expensive and mounting the digital tuner 36 in the vertical direction perpendicular to the small-size digital substrate 40 makes it possible to reduce the occupied area in which the digital tuner 36 is mounted and thereby reduce the parts cost of the digital substrate 30, and moreover, since the separation section 26 and shaving 27 which can be worked into a trapezoid shape are provided in the shielding case 39, it is possible to adapt the device to the direction in which the digital tuner 36 is mounted in the common shielding case 39 and even assemble the digital substrates 30, 40 of different sizes in the shielding case 39, achieve commonality of parts in this way and thereby realize a costs reduction.

Moreover, the plate spring 20 is a metal fragment having heat conductivity, one end of which is fixed to the top cover 39a, the radiation member 13 is pushed against it and urged elastically, and therefore it is possible to reliably make the plate spring 20 contact the radiation member 13 on the top surface of the video processing section 12 which is an heat-generating part, efficiently radiate heat generated from the video processing section 12 in particular which becomes easily hot and suppress radiation noise generated from this video processing section 12 by wrapping around it with shielding case 39 on the substrates 30, 40. Therefore, it is possible to avoid failures and damages that may be caused by these factors. Furthermore, the plate spring 20 is an independent part and can also change its fixed position according to the position of the radiation member 13 as appropriate.

Furthermore, in this embodiment, the video processing section 12 constitutes a heat-generating part, the present invention is of course not limited to this and the plate spring 20 may also be molded integral with the shielding case 39.

As examples of the digital circuit substrates 30, 40 having different sizes, this embodiment has explained the cases where the card slot 38 is mounted or not mounted, where the digital tuner 36 is placed upright in the vertical direction and where the digital tuner 36 is placed face down, but the present invention is not limited to these parts, and the present invention is also naturally applicable to other parts or a circuit substrate constituting a different circuit and similar effects can be obtained with not only the digital television 1 but also various electronic apparatuses which can receive digital broadcasting.

The effects of the present invention are as follows.

According to the first aspect of the present invention, the digital broadcasting reception device is a digital broadcasting reception device comprising a metal shielding case which wraps around a substrate mounted with an electronic part, wherein the digital broadcasting reception device forms a detachable separation section in the shielding case, forms parallel grooves in the shielding case in such a way that a shaving can be formed, accommodates, when a substrate having substantially the same size as that of the shielding case is accommodated in the shielding case, the substrate without detaching the separation section or raising the shaving, raises the shaving, when a substrate smaller than this substrate is accommodated in the shielding case, mounts the small substrate on this shaving, detaches the separation section from the shielding case when the height of the part mounted on the small substrate exceeds the height of the shielding case, and provides the part whose height exceeds the height of the shielding case in the space produced by this detachment, and therefore it is not necessary to manufacture a plurality of types of shielding cases for different substrates, it is possible to achieve commonality of the shielding case and thereby provide a digital broadcasting reception device capable of reducing the manufacturing cost and achieve a cost reduction.

According to the second aspect of the present invention, the part whose height exceeds the height of the shielding case mounted on the small substrate in the first aspect of the present invention is a digital tuner, the digital tuner is mounted face down in the horizontal direction on the substrate having substantially the same size as that of the shielding case, whereas the digital tuner is mounted upright in the vertical direction on the small substrate, and therefore it is possible to mount the digital tuner on even a small substrate by providing the digital tuner in the vertical direction, also accommodate the digital tuner in the shielding case and the use of the common shielding case can reduce the cost.

What is claimed is:

1. A digital broadcasting reception device comprising a metal shielding case which wraps around a substrate mounted with an electronic part,
wherein the digital broadcasting reception device forms a detachable separation section in the shielding case,
forms parallel grooves in the shielding case in such a way that a shaving can be formed,
accommodates, when a substrate having substantially the same size as that of the shielding case is accommodated in the shielding case, the substrate without detaching the separation section or raising the shaving,
raises the shaving, when a substrate smaller than this substrate is accommodated in the shielding case,
mounts the small substrate on this shaving,
detaches the separation section from the shielding case when the height of the part mounted on the small substrate exceeds the height of the shielding case, and
provides the part whose height exceeds the height of the shielding case in the space produced by the detachment.

2. The digital broadcasting reception device according to claim 1, wherein the part whose height exceeds the height of the shielding case mounted on the small substrate is a digital tuner, the digital tuner is mounted face down in the horizontal direction on the substrate having substantially the same size as that of the shielding case, whereas the digital tuner is mounted upright in the vertical direction on the small substrate.
